(19) United States
(12) Patent Application Publication
(10) Pub. No.: US 2013/0277858 A1
(43) Pub. Date: Oct. 24, 2013

(54) ELECTRICAL INTERCONNECTION STRUCTURE AND ELECTRICAL INTERCONNECTION METHOD

(71) Applicant: SILICONWARE PRECISION INDUSTRIES CO., LTD., Taichung (TW)

(72) Inventors: Tse-Shih Sung, Taichung Hsien (TW); Wen-Jung Chiang, Taichung Hsien (TW); Hsin-Hung Lee, Taichung Hsien (TW)

(73) Assignee: Siliconware Precision Industries Co., Ltd., Taichung (TW)

(21) Appl. No.: 13/628,620

(22) Filed: Sep. 27, 2012

(30) Foreign Application Priority Data
Apr. 24, 2012 (TW) 101114479

(51) Int. Cl. H01L 23/48

(52) U.S. Cl. 257/774; 257/E23.011

(57) ABSTRACT

An electrical interconnection structure includes: a signal transmission structure having a first through silicon via (TSV) and signal circuits connected to two opposite ends of the first TSV, respectively; and a grounding structure having a second TSV and grounding layers connected to two opposite ends of the second TSV, respectively. The grounding layers surround the signal circuits along the pathways thereof such that the ends of the first TSV are surrounded by the grounding layers with gaps therebetween. By changing the gaps between the grounding layers and the ends of the first TSV, the capacitance between the grounding layers and the signal circuits is adjusted so as to regulate the impedance therebetween.

### BACKGROUND OF THE INVENTION

1. Field of the Invention

The present invention relates to semiconductor stacking technologies, and, more particularly, to an electrical interconnection structure and electrical interconnection method in a three-dimensional (3D) chipset.

2. Description of Related Art

Along with the increasing demands of consumers for multi-functional and miniaturized electronic products, more and more electronic components and functions have to be integrated in a given area of a substrate. Accordingly, three-dimensional stacking technologies are developed.

Furthermore, redistribution layers (RDL), through silicon vias (TSV) and conductive bumps are provided to serve as electrical interconnection structures for signal transmission so as to increase the operation speed and bandwidth.

FIG. 1A is a schematic perspective view of a conventional electrical interconnection structure 1. Referring to FIG. 1A, the electrical interconnection structure 1 has a signal transmission structure 11 and two grounding structures 12a and 12b.

In the signal transmission structure 11, an electrical signal from a lower-layer signal circuit 114 is transmitted through a conductive bump 112 and a TSV 110 to an upper-layer signal circuit 116.

In each of the grounding structures 12a and 12b, a lower-layer grounding circuit 124 is electrically connected to an upper-layer grounding circuit 126 through a conductive bump 122 and a TSV 120.

In the above-described structure, the two grounding structures 12a and 12b are positioned at left and right sides of the signal transmission structure 11, respectively, and a gap d is formed between two opposite ends of the TSV 110 and the grounding circuits 124 and 126.

However, since the pathways of the grounding structures 12a and 12b are fixed, the value of the gap d cannot be changed. Consequently, the capacitance between the grounding circuits 124 and 126 and the signal circuits 114 and 116 can be adversely affected by a great value of the gap d.

Therefore, an obvious impedance mismatch (or discontinuity) can occur between the signal transmission structure 11 and the grounding structures 12a and 12b. For example, a high impedance variation k (usually 20% variation) is shown in FIG. 1B, which severely affects the waveform of the electrical signal and even reduces the signal integrity so as to result in a signal transmission error. As such, it is difficult to increase the operation speed and bandwidth of the structure due to a poor impedance match.

Therefore, there is a need to provide an electrical interconnection structure and method applicable in the 3D chip stacking technologies so as to improve impedance match.

### SUMMARY OF THE INVENTION

In view of the above-described drawbacks, the present invention provides an electrical interconnection structure disposed in a three-dimensional (3D) chipset, which comprises: a signal transmission structure having a first through silicon via (TSV) and signal circuits connected to two opposite ends of the first TSV, respectively; and a grounding structure having a second TSV and grounding layers connected to two opposite ends of the second TSV, respectively, wherein the grounding layers surround the signal circuits along the pathways of the signal circuits such that the ends of the first TSV are surrounded by the grounding layers with gaps formed therebetween.

The present invention further provides an electrical interconnection method for reducing impedance mismatch in a three-dimensional (3D) chipset, which comprises the steps of: forming a first signal circuit and a first grounding layer on a first surface of a substrate such that the first grounding layer surrounds the first signal circuit along the pathway of the first signal circuit; forming a first TSV and a second TSV in the substrate such that one end of the first TSV is connected to the first signal circuit and one end of the second TSV is connected to the first grounding layer, the end of the first TSV being surrounded by the first grounding layer with a gap formed therebetween; forming a second signal circuit and a second grounding layer on a second surface of the substrate opposite to the first surface such that the second grounding layer surrounds the second signal circuit along the pathway of the second signal circuit, wherein the other end of the first TSV is surrounded by the second grounding layer with a gap formed therebetween; and changing the gaps so as to adjust the capacitance between the grounding layers and the signal circuits, thereby regulating the impedance between the signal circuits and the grounding layers.

In the above-described electrical interconnection structure and method, the grounding layers can be made of a conductive material.

In the above-described electrical interconnection structure and method, the signal circuits can be made of a conductive material.

Compared with the prior art, the present invention can adjust the capacitance between the grounding layers and the signal circuits by changing the gaps between the grounding layers and the ends of the first TSV, thereby regulating the impedance therebetween. Therefore, the present invention can achieve a preferred impedance match performance so as to increase the operation speed and bandwidth in the 3D chip stacking technologies.

### BRIEF DESCRIPTION OF DRAWINGS

FIG. 1A is a schematic perspective view of a conventional electrical interconnection structure;

FIG. 1B is a diagram showing variation of the impedance between signal transmission and grounding structures in the conventional electrical interconnection structure;

FIG. 2A is a schematic perspective view of an electrical interconnection structure according to the present invention; and

FIG. 2B is a diagram showing variation of the impedance between signal circuits and grounding layers in the electrical interconnection structure according to the present invention.

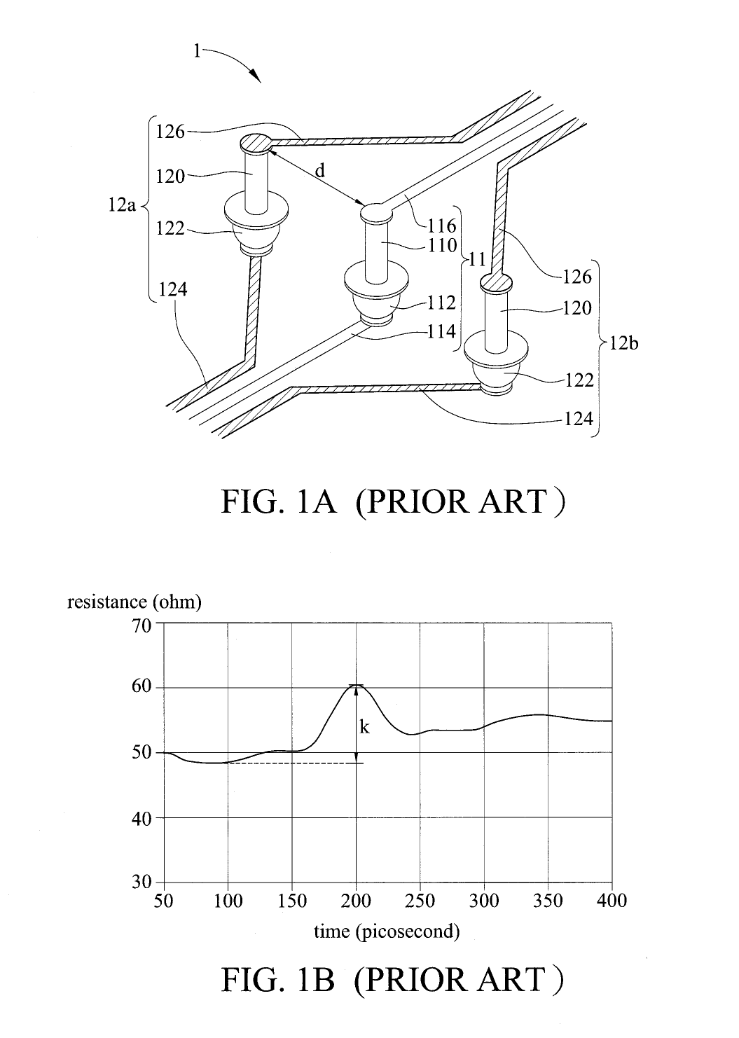

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms such as ‘end’, ‘on’, ‘a’ etc. are only used as a matter of descriptive convenience and not intended to have any other significance or provide limitations for the present invention.

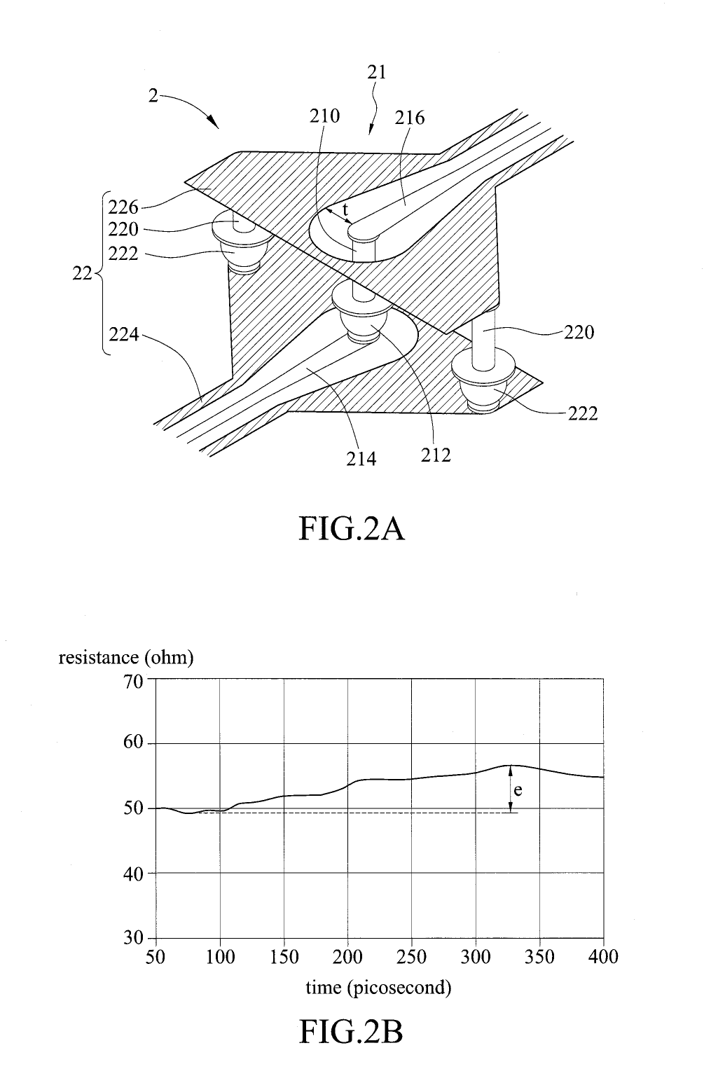

FIG. 2A is a schematic perspective view showing an electrical interconnection structure 2 according to the present invention. Referring to FIG. 2A, the electrical interconnection structure 2 has a signal transmission structure 21 and a grounding structure 22.

The signal transmission structure 21 has a first TSV 210, a lower signal circuit 214, an upper signal circuit 216 and a conductive bump 212. The grounding structure 22 has two second TSVs 220, a lower grounding layer 224, an upper grounding layer 226 and two conductive bumps 222.

The first TSV 210 is disposed in a substrate (not shown) and penetrates the substrate so as to extend from an upper surface of the substrate to an opposite lower surface of the substrate. The substrate can be a silicon wafer, a semiconductor die, a chip, or a printed circuit board.

The two second TSVs 220 are disposed in the substrate and disposed at two sides of the first TSV 210, respectively. Each of the second TSVs 220 penetrates the upper and lower surfaces of the substrate and has a predetermined gap from the first TSV 220. It should be noted that the predetermined gap can be adjusted according to the process precision and the user requirement. Generally, a smaller gap is required in a more advanced process.

The signal circuits 214 and 216 extend on the lower and upper surfaces of the substrate, respectively. The lower signal circuit 214 is electrically connected to a lower end of the first TSV 210 through the conductive bump 212, and the upper signal circuit 216 is directly electrically connected to an upper end of the first TSV 210. As such, the signal circuits 214 and 216 are electrically connected through the first TSV 210.

The grounding layers 224 and 226 are disposed on the lower and upper surfaces of the substrate, respectively. The lower grounding layer 224 surrounds the lower signal circuit 214 along the pathway of the lower signal circuit 214 such that the lower end of the first TSV 210 is surrounded by the lower grounding layer 224 with a gap t therebetween. Similarly, the upper grounding layer 226 surrounds the upper signal circuit 216 along the pathway of the upper signal circuit 216 such that the upper end of the first TSV 210 is surrounded by the upper grounding layer 226 with a gap t formed therebetween.

In the present embodiment, the grounding layers 224 and 226 can be regarded as having open areas so as for the signal circuits 214 and 216 to be disposed therein, respectively.

Further, the gap t can be changed so as to adjust the capacitance between the grounding layers 224 and 226 and the signal circuits 214 and 216, thereby regulating the impedance therebetween. Referring to FIG. 2B, the electrical interconnection structure 2 according to the present invention has a low impedance variation e (not greater than 3% variation), thereby reducing the signal distortion and improving the signal integrity.

In an embodiment, the signal circuits 214 and 216 and the grounding layers 224 and 226 are made of conductive materials.

Further, a dielectric material (not shown) made of silicon dioxide or silicon nitride can be formed between the signal circuits 214 and 216 and the grounding layers 224 and 226. Therefore, the impedance between the signal circuits 214 and 216 and the grounding layers 224 and 226 can be adjusted by using dielectric materials of different dielectric constants.

According to the present invention, the gaps between the grounding layers and the ends of the first TSV can be changed so as to adjust the capacitance between the grounding layers and the signal circuits, thereby regulating the impedance therebetween. Therefore, the present invention can achieve a preferred impedance match performance so as to increase the operation speed and bandwidth in the 3D chip stacking technologies.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. An electrical interconnection structure disposed in a three-dimensional (3D) chipset, comprising:
a signal transmission mechanism having a first through silicon via (TSV) and signal circuits connected to two opposite ends of the first TSV, respectively; and
a grounding mechanism having a second TSV and grounding layers connected to two opposite ends of the second TSV, respectively, wherein the grounding layers surround the signal circuits along pathways of the signal circuits such that the ends of the first TSV are surrounded by the grounding layers with gaps formed therebetween.

2. The electrical interconnection structure of claim 1, wherein the grounding layers are made of a conductive material.

3. The electrical interconnection structure of claim 1, wherein the signal circuits are made of a conductive material.

4. An electrical interconnection method for reducing impedance mismatch in a three-dimensional (3D) chipset, comprising the steps of:
forming a first signal circuit and a first grounding layer on a first surface of a substrate such that the first grounding layer surrounds the first signal circuit along a pathway of the first signal circuit;
forming a first TSV and a second TSV in the substrate such that one end of the first TSV is connected to the first signal circuit and one end of the second TSV is connected to the first grounding layer, the end of the first TSV being surrounded by the first grounding layer with a gap formed therebetween;
forming a second signal circuit and a second grounding layer on a second surface of the substrate opposite to the first surface such that the second grounding layer surrounds the second signal circuit along a pathway of the second signal circuit, wherein the other end of the first TSV is surrounded by the second grounding layer with a gap formed therebetween; and
changing the gaps so as to adjust capacitance between the grounding layers and the signal circuits, thereby regulating impedance between the signal circuits and the grounding layers.

5. The electrical interconnection method of claim 4, wherein the grounding layers are made of a conductive material.

6. The electrical interconnection method of claim 4, wherein the signal circuits are made of a conductive material.
